(19) United States
(12) Patent Application Publication
(10) Pub. No.: US 2005/0285813 A1
(43) Pub. Date: Dec. 29, 2005

(54) Display controller, electronic equipment, and image data supplying method

(76) Inventor: Atsushi Obinata, Tokyo (JP)

Correspondence Address: HARNESS, DICKEY & PIERCE, P.L.C., P.O. BOX 828, BLOOMFIELD HILLS, MI, 48303, US

(21) Appl. No.: 11/157,012

(22) Filed: Jun. 20, 2005

(30) Foreign Application Priority Data
Jun. 23, 2004 (JP) 2004-185155

(51) Int. Cl. G09G 5/00; G09G 3/36; H03C 3/00

(52) U.S. Cl. 345/3.2; 345/3.1; 345/87; 332/117

(57) ABSTRACT

A display controller includes a UV sampling rate converter which converts a format of image data of a first YUV format from a host to a second YUV format by changing a U component and a V component, a memory in which image data of this converted second YUV format is stored, an image processor which writes image data in the memory after image processing is carried out on the image data of the second YUV format from the memory, and a format converter which converts the image data of the second YUV format from the memory to an RGB format. The display controller supplies image data, which has been converted to this RGB format, to a display driver.

### RELATED APPLICATIONS

This application claims priority to Japanese Patent Application No. 2004-185155 filed Jun. 23, 2004 which is hereby expressly incorporated by reference herein in its entirety.

### BACKGROUND

1. Technical Field

This invention relates to a display controller, electronic equipment, and an image data supplying method.

2. Related Art

In recent years, there are many cases of a display panel represented by a liquid crystal display (LCD) which is mounted on portable equipment (electronic equipment, in abroad sense) such as mobile phones. The display panel is driven by a display driver based on image data. The image data is, for example, captured by a camera module or generated or processed by a host. The display driver, upon receiving such image data and a display synchronous signal, performs drive control of the display panel. The display controller supplies this image data and the display synchronous signal for the host, thus enabling processing load of the host to be reduced.

Incidentally, various formats are defined for image data. Above all, a YUV format and an RGB format are used in many cases.

The YUV format can make a data size of image data smaller as compared to the RGB format through the use of characteristics of a human eye, while, at the same time, making compression processing such as JPEG (Joint Photographic Experts Group) and MPEG (Moving Picture Experts Group) more efficient. For example, image data of camera module is a YUV format.

On the other hand, the RGB format has image data in pixel units, so that it is suited for image data for display on the LCD panel. Further, processing image data in pixel units is facilitated to lend itself suited for image processing such as 3-dimensionl image processing carried out by the host and the like. For example, image data inputted/outputted between the host and the panel as well as image data outputted to the display driver is in the RGB format.

Now, in the display controller set up in lieu of the host, image data in the YUV format and the RGB format is inputted/outputted.

If the display controller is mounted on mobile equipment, low power consumption is required. As a result, it is preferable for the display controller to have a built-in video memory.

However, in a case where image data in the RGB format is stored in the video memory built in the display controller, so that image data read from the video memory is displayed on the LCD panel, capacity of the video memory becomes large as compared to memorizing YUV format image data. Consequently, it is desirable to store in the video memory YUV format image data of the data size smaller than the RGB format data size.

So accordingly, it is conceivable that a format of RBG format image data from the host is converted to a YUV format in the display controller, then, stored in the video memory (refer to Published Unexamined Patent No. 2003-224862). However, in this case, the host will access the video memory by means of image data of the RGB format whose data size is larger than the YUV format. Hence, the larger the display size becomes through expansion of the LCD panel display screen, the larger the data size to be accessed by the host becomes. And, as compared to a rate of increase of the data size of YUV format image data, the rate of increase of the data size of RGN format image data becomes extremely high.

Further, the larger the data size of image data to be transferred from the host to the video memory becomes, the longer transfer time of image data becomes. As a result, it takes longer to write image data, and flickering of images updated at a preset cycle may become noticeable or control of reading image data from the video memory may become complicated. And these appear conspicuously when image data of still pictures are rewritten consecutively or image data of dynamic images are rewritten.

Further, during this data transfer, the host becomes unable to do other processing, thus lowering overall system performance.

The present invention has been achieved in view of technical problems described above, and it is an object thereof to provide a display controller, electronic equipment, and a supply method of image data which can reduce the capacity of the video memory without deteriorating the image quality.

### SUMMARY

To solve the above-mentioned problems, the present invention relates to a display controller for supplying image data to a display driver, which drives a display panel, comprises: a UV sampling rate converter converting an image data format of a first YUV format from a host to a second YUV format by changing sampling rates of a U component and a V component of the image data; a memory in which image data of the second. YUV format converted by the UV sampling rate converter is stored; an image processor which subjects image data of the second YUV format read from the memory to specified image processing and writing image data after image processing as it is in the second YUV format in the memory; and a format converter converting image data of the second YUV format read from the memory to an RGB format, wherein image data converted by the format converter to the RGB format is supplied to the display driver.

Further, in the display controller according to the present invention, the UV sampling rate converter converts image data of the second YUV format read from the memory to the first YUV format by changing the sampling rates of the U component and the V component of the image data. Image data of the first YUV format converted by the UV sampling rate converter is supplied to the host.

According to the present invention, memory capacity can be reduced by comparison to a case of storing image data of an RGB format in the memory, and a case of storing image data of a YUV format while transferring image data of the RGB format between the host and the memory.

Further, since the YUV format is set as a format of image data to be accessed by the host with respect to the display controller, the rate of increase of the data size of image data to be accessed by the host can be held down. Consequently, even though the display size enlarges due to expansion of the display screen of the display panel, long transfer time of image data is held to a minimum, thereby realizing low power consumption and prevention of flickering of images. Moreover, since the transfer time of image data can be made short, that much time can be allocated to processing of the host such that performance of the display system is kept from diminishing.

Further, the display controller according to the present invention may be such that the first YUV format is either the YUV 4:1:1 format or the YUV 4:2:9 format, the second YUV format being the YUV4:2:2 format.

Further, the display controller according to the present invention comprises an input format setting register for setting an input format of image data from the host, wherein the first YUV format is a YUV 4:1:1 format, a YUV 4:2:0 format, or a YUV 4:2:2 format, the second YUV format being a YUV 4:2:2 format. When it is determined that image data from the host is the YUV 4:2:2 format based on a set value of the input format setting register, the UV sampling rate converter may supply the image data from the host as it is to the memory.

It is desirable that an image quality of images shown by image data subject to processing by the image processor is that which deteriorates as little as possible, and which accompanies no unnecessary processing when processing. Subjecting an image, whose image quality suffers a great deal of deterioration, to processing will not enable already lost data to be restored but, in many cases, aggravate the image quality even more. Further, if extra processing accompanies whenever a read operation is performed of the memory, that much work becomes a processing load on the image processor, thereby inviting a decrease in processing rate and an increase in power consumption. On the other hand, because the image data subject to processing by the image processor is stored in the memory, it is desirable for a memory capacity of the memory not to be too large.

According to the present invention, since a format of image data to be stored in the memory can be set as the YUV4:2:2 format, image processing can be carried out on the same level of image quality as the image data of the RGB 8:8:8 format, so that in return for saving the capacity of the memory, deterioration of the image quality can be prevented.

Further, the present invention relates to the display controller for supplying image data to the display driver driving the display panel, comprises: a host interface for inputting image data of the first YUV format from the host; a memory in which image data of the first YUV format inputted through the host interface is stored; an image processor which subjects image read from the memory to specified image processing and writing image data without changing the format of the image data after image processing in the memory; and a format converter converting image data of the first YUV format read from the memory to the RGB format, wherein image data converted by the format converter to the RGB format is supplied to the display driver.

Further, the display controller according to the present invention is such that the format converter, after converting the image data format of the first YUV format read from the memory to a second YUV format by changing sampling rates of a U component and a V component of the image data, converts the image data to an RGB format.

According to the present invention, the capacity of a memory may be reduced in comparison to a case of storing image data of the RGB format in the memory and a case of transferring image data of the RGB format between the memory and the host, despite storing image data of the YUV format in the memory.

Further, since the YUV format is set as a format of image data to be accessed by the host with respect to the display controller, the rate of increase of the data size of image data to be accessed by the host can be held down. Consequently, if the display size enlarges due to expansion of the display screen of the display panel, long transfer time of image data is held to a minimum, thereby realizing low power consumption and prevention of flickering of images. Moreover, since the transfer time of image data can be made short, that much time can be allocated to processing of the host such that performance of the display system is kept from diminishing.

Further, the display controller according to the present invention may include a display driver interface for supplying image data of the RGB format converted by the format converter to the display driver.

The display controller according to the present invention is such that the image processor includes at least one of a scaling circuit performing processing to expand or reduce an image size of the image data read from the memory and an image effect arithmetic circuit performing specified effect processing with respect to the image data read from the memory.

Further, the present invention relates to electronic equipment which includes a display panel, display controller according to any of the above, and a display driver which drives the above-mentioned display panel based on image data supplied by the above-mentioned display controller.

Further, in electronic equipment according to the present invention, there may be included a host which inputs/outputs image data between the above-mentioned display controller and the equipment.

According to the present invention, there may be provided electronic equipment capable of reducing the capacity of a memory built in the display controller without deteriorating the image quality and improving system performance by diminishing processing load by the host.

Further, the present invention relates to an image data supplying method for supplying image data to the display driver driving the display panel, wherein image data format of a first YUV format from the host is converted to the second YUV format by changing sampling rates of the U component and the V component of the image data; image data of the second YUV format is stored in the memory; a format of image data read from the memory is converted to the RGB format and outputted to the display driver; image data stored in the memory is subjected to specified image processing after being read once from the memory to be written again in the memory after image processing.

Furthermore, the present invention relates to an image data supplying method for supplying image data to the display driver driving the display panel, wherein image data format of the first YUV format from the host is stored in the memory without conversion; an image data format of the first YUV format read from the memory is converted to the RGB format and outputted to the display driver; image data stored in the memory is subjected to specified image processing after being read once from the memory to be written again in the memory after image processing.

### BRIEF DESCRIPTION OF THE DRAWINGS

FIG. 1 is a block diagram of a configuration example of a display system to which a display controller in the present embodiment is applied;

FIG. 2 is a block diagram of a configuration example of a display controller in the present embodiment;

FIG. 3 is an explanatory diagram of the RGB format and the YUV format;

FIG. 4 is a block diagram of a configuration example of a display controller of a first comparison example in the present embodiment;

FIG. 5 is a block diagram of a configuration example of a display controller of a second comparison example in the present embodiment;

FIG. 6 is a block diagram of a hardware configuration example of a display controller in the present embodiment;

FIG. 7 is a diagram showing an operating example of access of an image processing circuit with respect to a memory access arbitration. circuit;

FIG. 8 is a block diagram of a configuration example of constituent features of the UV sampling rate converting circuit of FIG. 6;

FIG. 9A-C are explanatory diagrams of operation of the UV sampling rate converting circuit of FIG. 6;

FIG. 10A-C are explanatory diagrams of operation of the UV sampling rate converting circuit;

FIG. 11 is a diagram showing a conversion matrix of conversion processing of a format converting circuit;

FIG. 12 is a block diagram of a configuration example of a format converting circuit:

FIG. 13 is an explanatory diagram of shift addition operation in a format converting circuit;

FIG. 14 is a timing diagram of an operating example of a format converting circuit;

FIG. 15 is a block diagram of a configuration example of an image processing circuit in FIG. 6;

FIG. 16 is an explanatory diagram of operation of an image effect arithmetic circuit in FIG. 15;

FIG. 17 is a block diagram of a configuration example of a scaling circuit of FIG. 15;

FIG. 18 is an explanatory diagram of a vertical synchronous signal and the like;

FIG. 19 is a block diagram of a configuration example of a horizontal direction thinning circuit in FIG. 17;

FIG. 20 is an explanatory diagram of a horizontal contraction rate;

FIG. 21 is a timing diagram of an operating example of a horizontal direction thinning circuit;

FIG. 22 is a block diagram of a configuration example of a display controller in a variation example of the present embodiment; and

FIG. 23 is a block diagram of a configuration example of a format converter of a display controller in a variation example.

FIG. 24 is a block diagram of a configuration example of electronic equipment in the present embodiment.

### DETAILED DESCRIPTION

Embodiment of the present invention will be described in detail below with reference to the drawings. It is to be noted that the embodiment described below does not unjustly limit the content of the present invention described in the claims. Further, all the configurations described below do not necessarily constitute the essential composing elements.

1. Display Controller

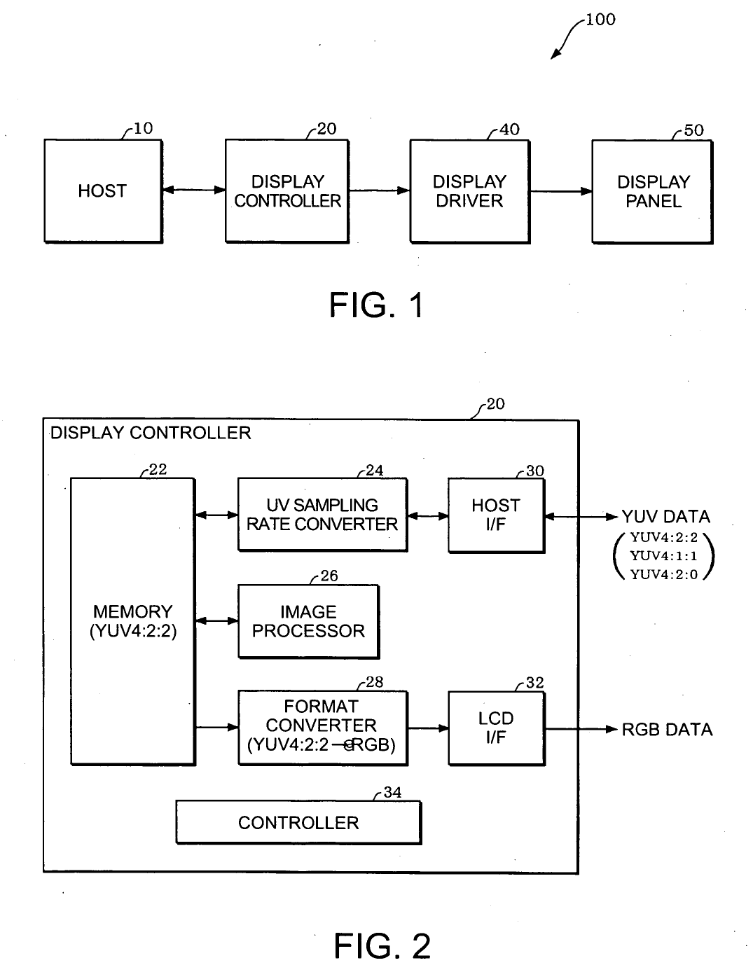

FIG. 1 shows a configuration example of a display system to which a display controller in the present embodiment is applied. For example, the display system shown in FIG. 1 is mounted on electronic equipment.

A display system 100 comprises a host 10, a display controller 20, a display driver 40, and a display panel 50. The host 10 has a CPU (Central Processing Unit) and a memory, and a specified function is realized as the CPU which reads a program stored in the memory executes processing corresponding to the program. At this point, the host 10 generates or processes image data corresponding to an image shown on the display panel 50 and supplies it to the display controller 20.

The display controller 20 supplies image data from the host to the display driver 40 driving the display panel 50. At this time, the display controller 20 can also process image data such as scaling processing to enlarge or reduce an image size and image effect processing.

The display driver 40 can drive the display panel 50 based on image data from the display controller 20. As the display panel 50, for example, an LCD panel of an active matrix type or a simple matrix type maybe employed.

In this manner, the display controller 20, being provided between the host 10 and the display driver 40, can reduce a processing load of the host 10.

In FIG. 2, there is shown a block diagram of a configuration example of the display controller 20 in the present embodiment.

The display controller 20 has a memory 22 which functions as a video memory, and, after storing image data of a YUV format from the host 10 in the memory 22, converts the format of the image data to an RGB format and supplies it as the image data (RGB data) of the RGB format to the display driver 40.

Consequently, the display controller 20 includes a UV sampling rate converter (UV sampling rate converter) 24. The UV sampling rate converter 24 converting an image data format of the first YUV format from the host 10 to the second YUV format by changing sampling rates of the U component and the V component of the image data. And in the memory 22, there is stored image data of the second YUV format which is converted by the UV sampling rate converter 24.

Further, the display controller 20 includes an image processor 26. The image processor 26 is such that specified image processing is performed with respect to image data of the second YUV format which is read from the memory 22, so that image data after image processing may be written into the memory 22 with the second YUV format as it is.

Further, the display controller 20 includes a format converter 28. The format converter 28 converts image data of the second YUV format read from the memory to an RGB format, and the display controller 20 supplies image data, which is converted by the format converter 28 to the RGB format, to the display driver.

It is to be noted that the UV sampling rate converter 24 converts a format of image data of the second YUV format read from the memory 22 to the first YUV format by changing the sampling rates of the U component and the V component of the image data. And image data of the first YUV format converted by the UV sampling rate converter 24 may be supplied to the host.

The display controller 20 includes a host interface (I/F) circuit (host interface in a broad sense) 30 and an LCD I/F circuit (driver interface in a broad sense) 32. In the host I/F circuit 30, there is inputted image data of the first YUV format from the host 10. At this time, the host I/F circuit 30 performs interface processing (receiving processing between the host and the display controller, and buffering of a signal) and supplies image data after interface processing to the UV sampling rate converter 24. Further, when supplying image data of the first YUV format, which is converted by the UV sampling rate converter 24, to the host 10, in the host I/F circuit 30, there is inputted image data of the first YUV format from the UV sampling rate converter 24. The host I/F circuit 30 performs interface processing (transmission processing between the host and the display controller, and buffering of a signal) and supplies image data after interface processing to the host 10.

The LCD I/F circuit 32 outputs image data (RGB data) of the RGB format from the format converter 28 to the display driver 40. The LCD I/F circuit 32 performs interface processing (transmission processing between itself and the display driver, and buffering of a signal) of image data and outputs image data after the interface processing to the display driver 40.

Further, the display controller 20 includes a controller 34 and the controller 34 takes charge of controlling each part of the display controller 20.

In the present embodiment, the image processor 26 is such as to be capable of performing specified image processing with respect to image data stored in the memory 22. The image processor 26 performs at least one of the scaling processing to enlarge or contract the image size of image data and specified effect processing. As this effect processing, there is equalization processing to express blurring of an image.

Consequently, the image quality of an image shown by image data subject to processing by the image processor 26 is preferably that which deteriorates as little as possible with no accompaniment of processing unnecessary in carrying out the processing. Even if image processing of an image having a severe degree of deterioration is carried out, it is impossible to restore data which has already been lost, and in many cases, it may lead to aggravating the image quality even more. Further, if extra processing follows whenever reading from the memory 22, that portion becomes a processing load of the image processor 26, thereby inviting reduction of the processing rate and the increase in power consumption.

On the other hand, because the image data subject to processing by the image processor 26 is stored in the memory 22, it is desirable for the memory capacity of the memory 22 not to be too large.

Therefore, in the present embodiment, a format of image data to be stored in the memory 22 is set to the YUV 4:2:2 format.

Now, the format of image data affecting the data size and the image quality of image data will be described.

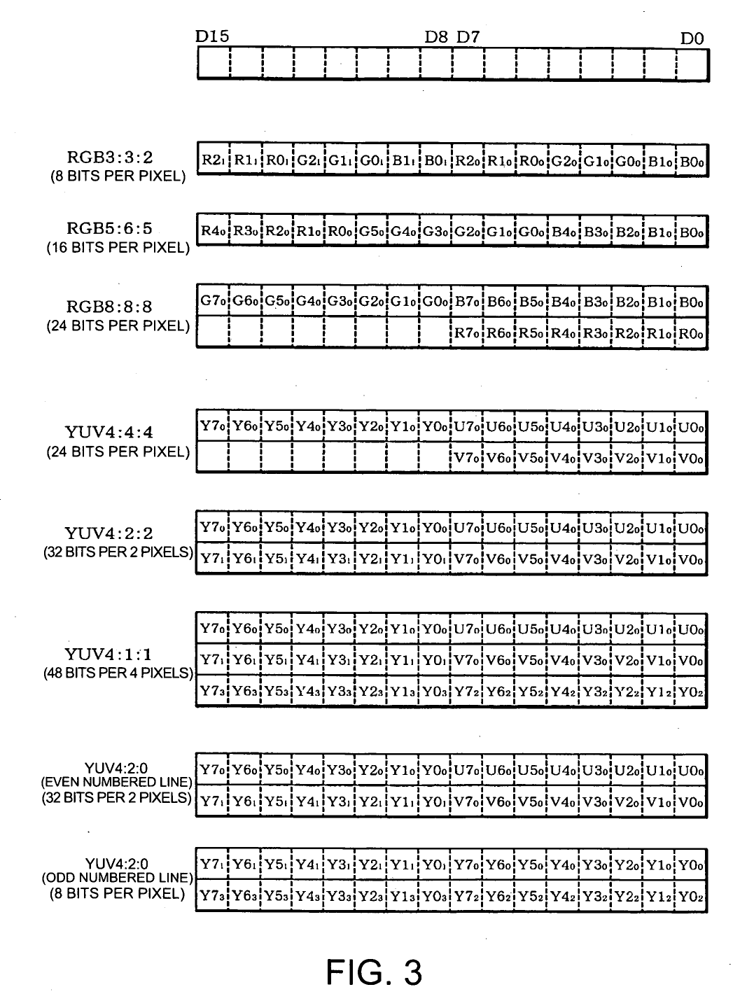

FIG. 3 shows an explanatory diagram of formats of image data.

The RGB format treats a group of data set up for each color component constituting one pixel as one unit. In the RGB formats, there are an RGB 3:3:2 format, an RGB 5:6:5 format, an RGB 8:8:8 format, and the like.

Image data of the RGB 3:3:2 format is constituted by 8 bits per pixel. Namely, each pixel is expressed by an R component of 3 bits, a G component of 3 bits, and a B component of 2 bits. Image data of the RGB 5:6:5 format is constituted by 16 bits per pixel. Namely, each pixel is expressed by an R component of 5 bits, a G component of 6 bits, and a B component of 5 bits. Image data of the RGB 8:8:8 format is constituted by 24 bits per pixel. Namely, each pixel is expressed by an R component of 8 bits, a G component of 8 bits, and a B component of 8 bits.

In the RGB format, the more bit per pixel increases, the more number of colors to express one pixel increases. However, since 3 bytes are treated as 1 unit in the RGB 8:8:8 format, image data of the RGB 8:8:8 format is difficult for software and hardware to handle and 4 bytes are often treated as 1 unit by adding a dummy of 1 byte. Consequently, the data size of image data grows even larger.

The YUV format has, as 1 unit, a group of data having a brightness component of a pixel and 1 or 2 kinds of color difference component. In the YUV formats, there are a YUV 4:4:4 format, a YUV 4:4:4 format, a YUV 4:1:1 format, a YUV 4:2:0 format, and the like.

Image data of the YUV 4:4:4 format is constituted by 24 bits per pixel. Namely, each pixel is expressed by a brightness component Y of 8 bits, a color difference component U of 8 bits, and a color difference component V of 8 bits. Image data of the RGB 5:6:5 format is constituted by 16 bits per pixel. The YUV 4:4:4 format has the same image quality as the image quality expressed by image data of the RGB 8:8:8 format and it is not different from its constitution of 25 bits per pixel.

Image data of the YUV 4:2:2 format is constituted by 32 bits per 2 pixels. Namely, each pixel has a brightness component Y of 8 bits, a color difference component U of 8 bits and a color difference component V of 8 bits per 2 pixels adjacent in a horizontal direction. In other words, each color difference component is shared. In a case of a natural image, the image quality of the YUV 4:2:2 format is on the same level as the RGB 8:8:8 format to such an extent that cannot be distinguished by the human eye, but 16 bits per pixel suffices.

Image data of the YUV 4:1:1 format is constituted by 48 bits per 4 pixels. Namely, each pixel has a brightness component Y of 8 bits, a color difference component U of 8 bits and a color difference component V of 8 bits per 4 pixels adjacent in the horizontal direction. In other words, each color difference component is shared by 4 pixels. While the YUV 4:1:1 format has an image quality inferior to the image quality of the YUV 4:2:2 format, its data size can be made smaller than the YUV 4:2:2 format.

The YUV 4:2:0 format is different for each line of even numbered lines and odd numbered lines arranged in a vertical direction. In the case of the even numbered line, image data of the YUV 4:2:0 format is constituted by 32 bits per 2 pixels. Namely, It has a brightness component Y of 8 bits per pixel, a color difference component U of 8 bits and a color difference component V of 8 bits per 2 pixels adjacent in the horizontal direction. In other words, each color difference component is shared by 2 pixels. In a case of the odd number line, image data of the YUV 4:2:0 format only has the brightness component Y of 8 bits per pixel, and for color difference components U and V of each pixel, the color difference components of the even numbered line are used. As a result, the data sizes of the YUV 4:2:0 format and the YUV 4:1:1: format become equal.

Focusing on such format characteristics of image data, in the present embodiment, a format of image data stored in the memory 22 is set as the YUV 4:2:2 format. Namely, as the second YUV format, the YUV 4:2:2 format is employed. Consequently, as the first YUV format which is a format of image data from the host 10, the YUV 4:1:1 format or the YUV 4:2:0 format may be employed.

It is to be noted that it is possible to set the format of image data from the host 10 as the YUV 4:2:2 format. In this case, there are provided means of distinguishing an input format of image data from the host 10, and when it is determined that the format of image data from the host 10 is the YUV 4:2:2 format, what is required is for the UV sampling rate converter 24 to supply image data from the host 10 as it is to the memory 22 (processing of the UV sampling rate converter omitted).

Next, the present embodiment will be described by comparison to comparison examples of the present embodiment.

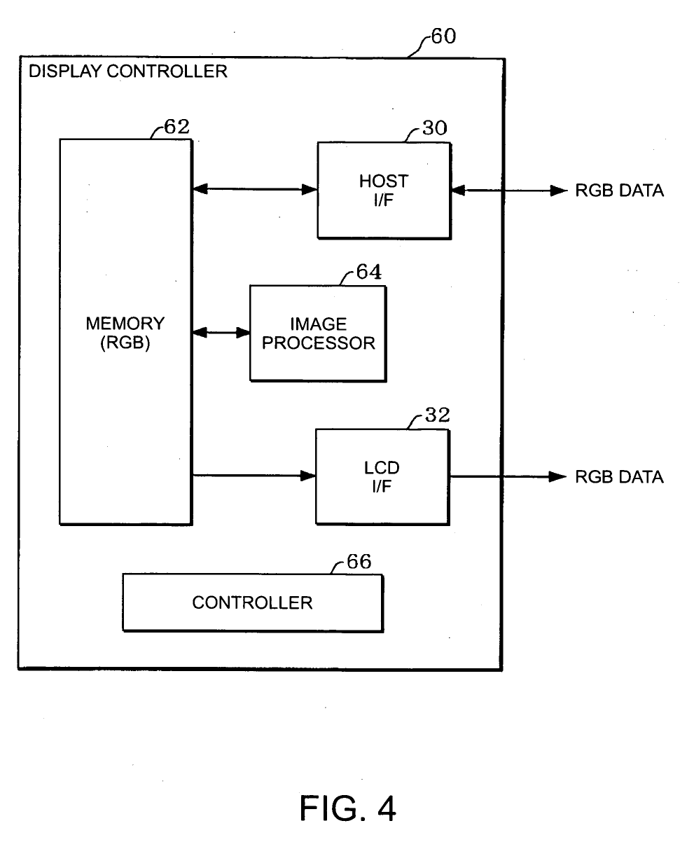

FIG. 4 shows a block diagram of an outline of configuration of a display controller in a first comparison example of the present embodiment. However, like reference numerals designate like parts of FIG. 2 with description omitted as necessary.

But, a display controller 60 in the first comparison example includes a host I/F circuit 30, an LCD I/F circuit 32, a memory 62, an image converter 64, and a controller 66. The image processor 64 can realize a function of the image processor 26 of FIG. 2.

Nevertheless, in the first comparison example, there is inputted/outputted image data of the RGB format between the host and the memory. And in the memory 62, image date of the RGB format is stored. As a result, the image processor 64 performs the above-mentioned image processing with respect to image data of the RGB format. Further, the LCD I/F circuit 32 supplies image data to the display driver without subjecting image data read from the memory 62 to format conversion.

The controller 656 takes charge of controlling such display controller 60.

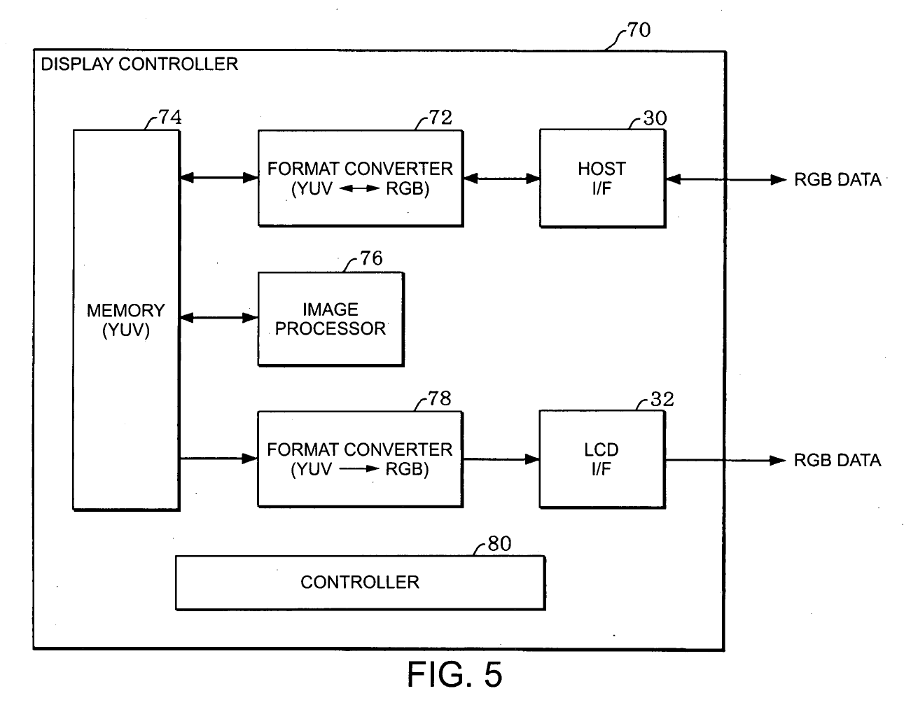

In FIG. 5, there is shown a block diagram of an outline of configuration of a display controller in a second comparison example of the present embodiment. However, like reference numerals designate like parts of FIG. 2 with description omitted as necessary.

A display controller 70 in the second comparison example includes the host I/F circuit 30, a format converter 72, a memory 74, an image processor 76, a format converter 78, the LCD I/F circuit 32, and a controller 80. The image processor 76 can realize a function of the image processor 26 of FIG. 2.

Nevertheless, in the second comparison example, there is inputted/outputted image data of the RGB format between the host and the memory. And a format converter 72 is provided between the host I/F circuit 30 and the memory 74. The format converter 72 performs format conversion between the YUV format and the RGB format. As a result, in the memory 74, there is stored image data of the YUV format. When image data of the RGB format is outputted from the host I/F circuit 30 to the host, image data read from the memory 74 is converted to the RGB format by means of the format converter 72.

Further, the image processor 76 performs the above-mentioned image processing with respect to image data of the YUV format of the memory 74.

Image data of the YUV format of the memory 74 is such that after it is converted by the format converter 78 to the RGB format, the LCD I/F circuit supplies post-conversion image data to the display driver.

The controller 80 takes charge of controlling the display controller 70 which performs such conversion.

In the first comparison example, to store image data of the RGB format in the memory 62, the memory capacity of the memory 62 is necessitated to be increased. On the other hand, in the second comparison example, because of storing image data of the RGB format in the memory 74, an increase in the memory capacity of the memory 74 can be avoided to some extent. But, in the first and the second comparison examples, transfer time becomes long because of transferring image data of the RGB format between the memory and the host, thereby inviting an increase in power consumption and a reduction of system performance.

On the other hand, in the display controller 20 in the present embodiment, it is designed such as to hold image date of the YUV format. Hence, as compared to the first and the second comparison examples, the capacity of the memory 22 as a video memory can be reduced.

Further, since a format of image data which the host 10 accesses with respect to the display controller 20 is set to be the YUV format, as compared to the first and the second comparison examples, it is possible to restrain a rate of increase of the data size of image data which the host 10 accesses. Consequently, even if the display size should grow through expansion of the display screen of the display panel 50, it is possible to realize low power consumption and prevention of image flickering by controlling the transfer time of image data. Furthermore, since the transfer time of the image data can be shortened, that portion saved can be allocated for processing of the host, thus enabling performance of the display system not to drop.

Moreover, in the present embodiment, as described above, image data of the YUV 4:2:2 format is arranged to be stored in the memory 22, so that image processing can be performed for the same level of image quality as image data of the RGB 8:8:8 format, thus preventing the image quality from deteriorating in return for conserving the capacity of the memory 22.

2. Configuration Example of the Display Controller

Next, a detailed example of hardware configuration of the display controller in the present embodiment will be described.

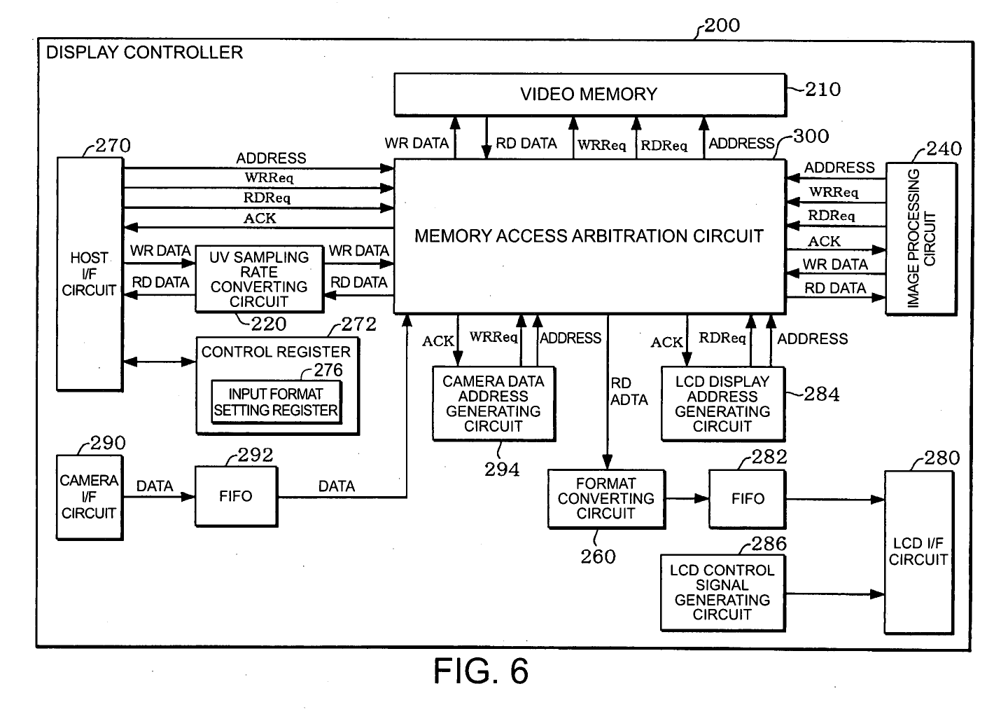

FIG. 6 shows a block diagram of a detailed example of hardware configuration of the display controller in the present embodiment.

In a display controller 200, function of the memory 22 of FIG. 2 is realized by a video memory 210. Further, function of the sampling rate converter 24 of FIG. 2 is realized by a UV sampling rate conversion circuit 220. Function of the image processor 26 of FIG. 2 is realized by an image processing circuit 240. Function of the format converter 28 of FIG. 2 is realized by a format conversion circuit 260. Further, function of the host I/F circuit 30 is realized by a host I/F circuit 270, and function of the LCD I/F circuit 32 of FIG. 2 is realized by an LCD I/F circuit 280. Further, the display controller 200 has a camera I/F circuit 290 (image data input interface in a broad sense). The camera I/F circuit 290 performs interface processing for inputting image data from a camera module operating as an un-illustrated image-pickup unit.

Further, function of the controller 34 of FIG. 2 is realized by a FIFO (First-In First-Out) 292 functioning as a FIFO memory circuit, a camera data address generating circuit 294, an FIFO 282, an LCD display address generating circuit 284, an LCD control signal generating circuit 286, a control register 272 and a memory access arbitration circuit 300.

The FIFO 292 functions as a receiving buffer of image data of the YUV format inputted into the camera I/F circuit 290 and outputs image data, which is captured into the FIFO 292, sequentially to the memory access arbitration circuit 300. The camera data address generating circuit 294 generates a write address of a write request signal RReq for writing in the video memory 210 image data which is outputted from the FIFO 292 to the memory access arbitration circuit 300.

The FIFO 282 functions as a transmission buffer of image data, which is outputted from the memory access arbitration circuit 300, and outputs image data, which is captured into the FIFO 282, sequentially to the LCD I/F circuit 280. The LCD display address generating circuit 284 generates a read address of a read request signal RDReq for reading image data from the video memory 210 and outputting it to the format conversion circuit 260. The format conversion circuit 260 converts a format of image data read from the video memory 210 to the RGB format and supplies it to the FIFO 282. The LCD control signal generating circuit 286 generates an LCD control signal which is a display synchronous signal such as a vertical synchronous signal supplied to the display driver together with image data outputted from the FIFO 282, a horizontal synchronous signal, and a dot clock

In the control register 272, there is set control data for controlling the display controller 200. Each part of the display controller 200 is controlled based on control data (set values) of the control register 272. The host sets control data in the control register 272 through the host I/F circuit 270. In FIG. 6, the control register 272 includes an input format setting register 276. In the input format setting register 276, there is set control data for designating a format of image data which the host inputs. Corresponding to control data set by the input format setting register 276, the UV sampling rate conversion circuit 220 changes sampling rates of the U component and the V component of image data. This input format setting register 276 functions as means of distinguishing an input format of image data from the host.

The image processing circuit 240, based on control data set by the control register 272, generates the read request signal RDReq for reading image data from the video memory 210, a read address of the video memory 210 in which the image data is stored, and the write request signal RReq for writing image data after image processing, and a write address.

And, the memory access arbitration circuit 300 arbitrates access of the image processing circuit 240, the camera I/F circuit 290, the LCD I/F circuit 280 and the host I/F circuit 270 (UV sampling rate conversion circuit 220) to the video memory 210. The memory access arbitration circuit 300 arbitrates a plurality of write request signals RReqs and a plurality of read request signals RReq, and notifies completion of a given access by means of an acknowledge signal ACK corresponding to the request signal to a circuit whose access is permitted as a result of arbitration.

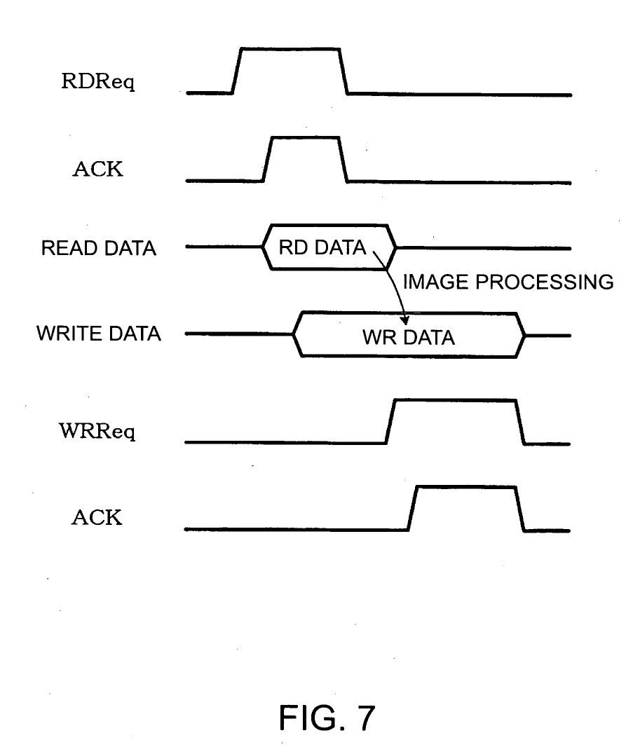

In FIG. 7, there is shown an example of access operation of the image processing circuit 240 with respect to the memory access arbitration circuit 300.

The image processing circuit 240 generates the read request signal RDReq a read address, the write request signal RReq, and a write address for outputting to the video memory 210 through the memory access arbitration circuit 300. The image processing circuit 240, while updating a read address on the basis of a read start address set in the control register 272, outputs the read address together with the read request signal RDReq. And completion of the access that started with this read request is notified by the acknowledge signal ACK.

Further, the image processing circuit 240, while updating a write address on the basis of a write start address set in the control register 272, outputs the write address together with the write request signal RReq and writes image data after image processing, which was carried out by the image processing circuit 240, in the video memory 210. And completion of the access that started with this write request is notified by the acknowledge signal ACK.

The same applies to other camera I/F circuit 290, LCD I/F circuit 280, and host I/F circuit 270 which make access requests to the video memory 210 with respect to the memory access arbitration circuit 300, and completion of the permitted access that started with this write request is notified by the acknowledge signal ACK.

Features of the display controller 200 will be described below in detail.

2.1 UV Sampling Rate Conversion Circuit

The UV sampling conversion circuit 220 of FIG. 6 realizes function of the UV sampling rate conversion circuit 24 of FIG. 2.

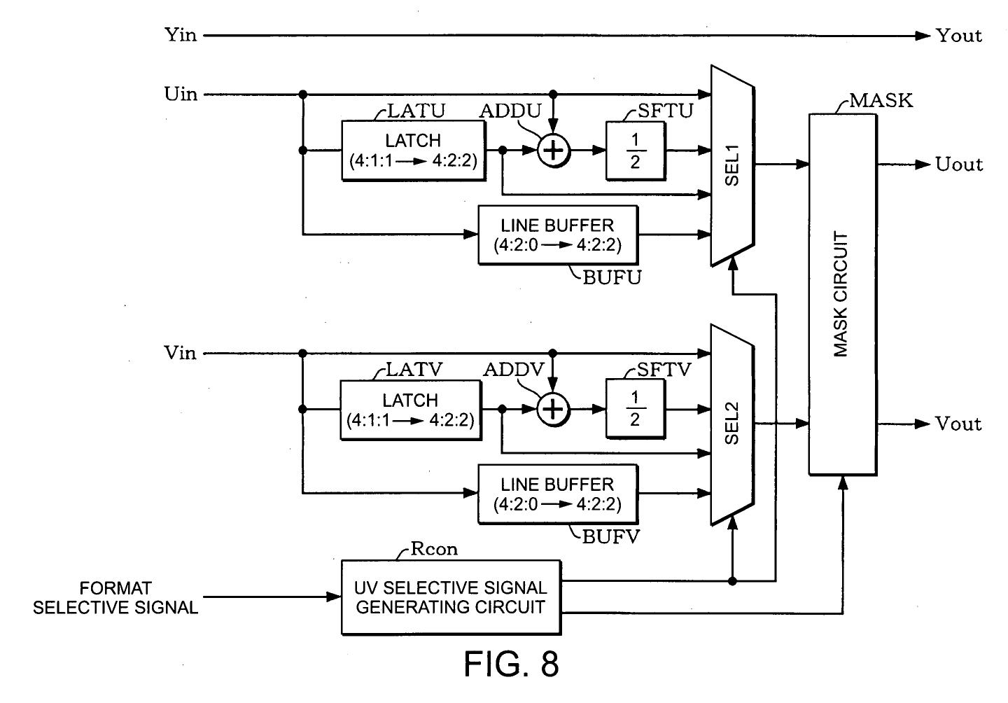

In FIG. 8, there is shown a configuration example of a constituent feature of the UV sampling rate conversion circuit 220 of FIG. 6. In FIG. 8, there are shown only parts generating image data (a Y component Yout of image data, a U component Uout of image data, and a V component Vout of image data) of the YUV format after conversion of sampling rates of the U component and the V component of image data (a Y component Yin of image data, a U component Um of image data, and a V component Vin of image data) of the YUV format inputted corresponding to format selective signals which are generated based on control data of the inputted format setting register 276. Consequently, it is possible to have a configuration as in FIG. 8 to supply image data from the host I/F circuit 270 to the memory access arbitration circuit 300 and to have a configuration as in FIG. 8 to supply image data from the memory access arbitration circuit 300 to the host I/F circuit 270. Further, there may be a configuration as in FIG. 8 in common for both directions.

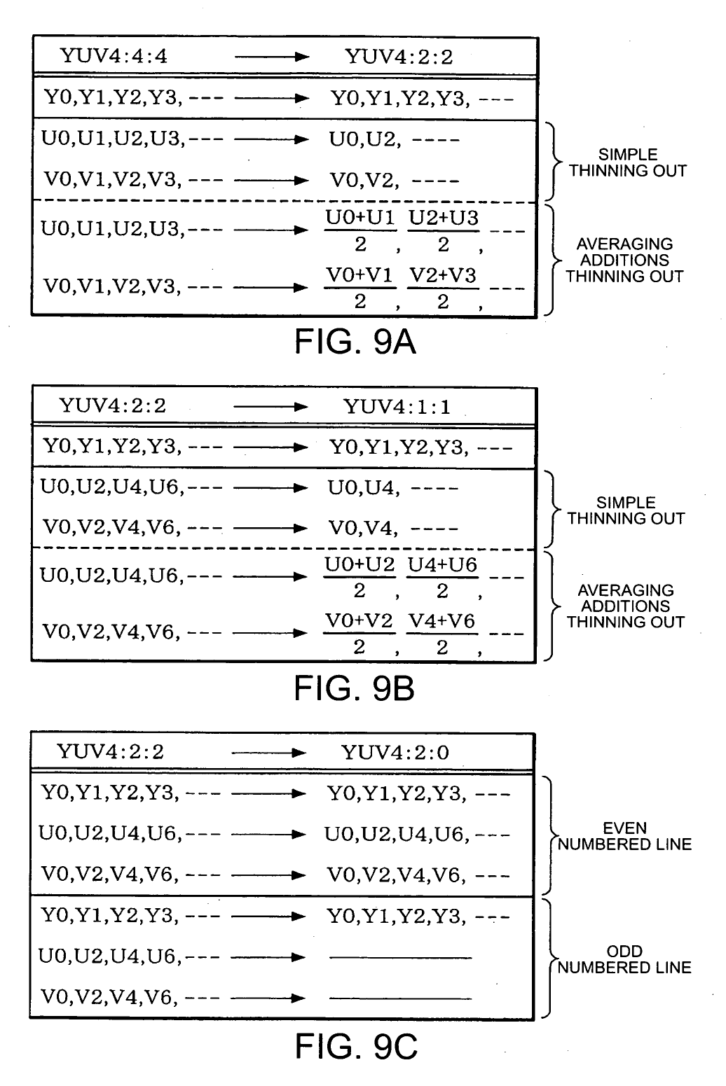

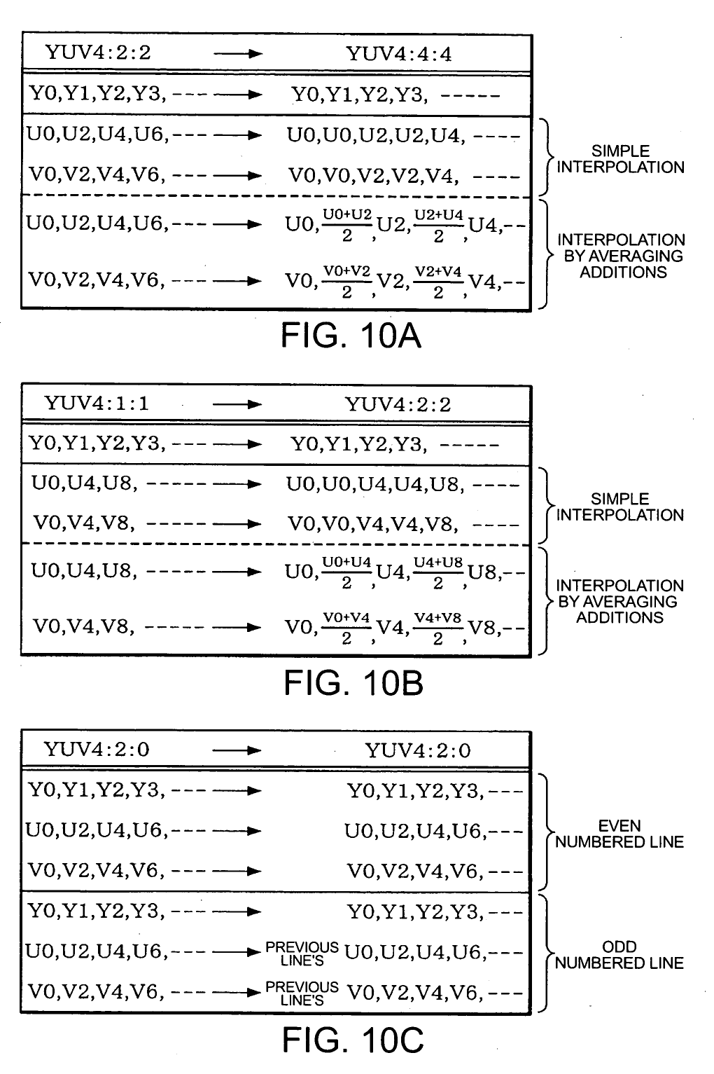

In FIG. 9A-C and FIG. 10A-C, there is shown an operation explanatory diagram of the UV sampling rate converting circuit 220.

In the configuration shown in FIG. 8, image data of the YUV 4:1:1 format of the YUV 4:2:2 format can be converted to the YUV 4:2:2 format. Further, image data of the YUV 4:2:2 format can be converted to the YUV 4:1:1 format or YUV 4:2:0 format.

Further, in the configuration shown in FIG. 8, a sampling rate conversion between the YUV 4:2:2 format and the YUV 4:4:4 format is possible, whereas FIG. 9A and FIG. 10A illustrate explanatory diagrams of operation. However, the UV sampling rate conversion circuit 220 does not need to support this conversion, because while, in the YUV 4:2:2 format, the image quality can be maintained on the same level as the RGB 8:8:8, it is possible to hold down the size of image data small. As a result, when the YUV 4:4:4 format is supported, reduction of the capacity of the video memory 210 becomes difficult.

Further, although it is not illustrated in FIG. 8, when outputting image data of the YUV 4:2:2 format as it is without format conversion, it is possible to bypass the UV sampling rate conversion circuit 220.

When converting image data of the YUV 4:2:2 to the YUV 4:1:1 format, it is outputted through simple thinning out or averaging additions of the U component and the V component after conversion.

In the case of simple thinning out, take the U component and the V component as a set, the U component and the V component after conversion are thinned out at a rate of once per 2 consecutive sets. In this case, a selector SEL 1 selects the U component Um and a selector SEL 2 selects the V component Vin, and as a mask circuit MASK masks selectors SELL and SEL 2 at a rate of once per 2 sets, a UV selective signal generating circuit Rcon generates a control signal.

In the case of averaging additions, the U component after conversion is subjected to averaging additions of 2 consecutive U components. In this case, the UV selective signal generating circuit Rcon generates a control signal so that the U component held by a latch LATU and a next U component are added by an adder ADDU, and that a result of that addition is cut in half by a shift circuit SFTU and outputted from the selector SEL 1 and the mask circuit MASK. The same as the U component applies to the V component.

When converting image data of the YUV 4:2:2 format to the YUV 4:2:0 format, as for the even numbered line, output the U component and the V component are outputted as they are, and as for the odd numbered line, the U component and the V component are deleted.

To be more specific, the UV selective signal generating circuit Rcon generates a control signal, so that in the case of the even number line, the selector SEL 1 and the mask circuit MASK output the U component Uin and the selector SEL 2 outputs the V component Vin, while in the case of the odd number line, the mask circuit MASK masks its output.

When converting image data of the YUV 4:1:1 format to the YUV 4:2:2 format, the U component and the V component after conversion are outputted by simple interpolation or interpolation by averaging additions.

In the case of simple interpolation, take the U component and the V component as a set. Then interpolate the U component and the V component of the set before conversion to provide 2 sets of the U component and the V component. In this case, the UV selective signal generating circuit Rcon generates a control signal, so that the selectors SEL 1 and SEL 2 and the mask circuit MASK output the U component Um and the V component Vin, and that as for the next pixel, the selectors SEL 1 and SEL 2 and the mask circuit MASK output the U component and the V component held by the latches LATU and LATV.

In the case of interpolation by averaging additions, the U component after conversion is interpolated by a mean of the consecutive U components, while the V components after conversion is interpolated by a mean of the consecutive V components. In this case, the UV selective signal generating circuit Rcon generates a control signal so that the selector SEL 1 and the mask circuit MASK output the U component Uin, and that as for the next pixel, the U component held by a latch LATU and a next U component are added by an adder ADDU, while a result of that addition is cut in half by the shift circuit SFTU and outputted from the selector SEL 1 and the mask circuit MASK. The same as the U component applies to the V component.

When converting image data of the YUV 4:2:0 format to the YUV 4:2:2 format, as for the even number line, the U component and the V component are outputted as they are and as for the odd number line, the U component and the V component of the previous line are outputted.

To be more specific, the UV selective signal generating circuit Rcon generates a control signal, so that in the case of the even number line, the selectors SEL 1 and SEL 2 output the U component Uin and the V component Vin, while in the case of the odd number line, the selectors SEL 1 and SEL 2 and the mask circuit MASK output outputs of line buffers BUFU and BUFV.

It is to be noted that when making a conversion between the YUV 4:4:4 format and the YUV 4:2:2, it is realized in the same way as shown in FIG. 9A and FIG. 10A.

A format conversion circuit 260 of FIG. 6 realizes function of the format converter 28 of FIG. 2.

2. 2 Format Converting Circuit

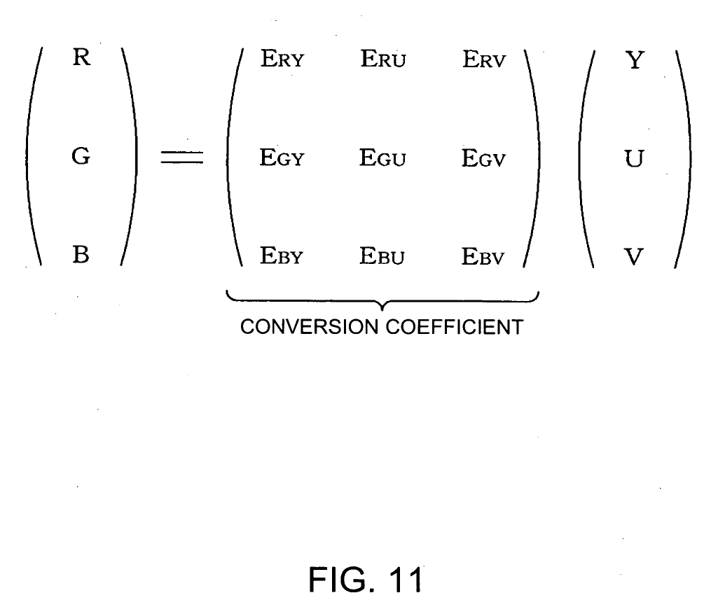

The format conversion circuit 260 performs conversion processing according to a conversion matrix shown in FIG. 11. When a conversion coefficient is made into a variable, a sum-of-product arithmetic circuit becomes necessary for hardware which realizes conversion processing according to the conversion matrix shown in FIG. 11, thus increasing the circuit size. In the present embodiment, by taking the conversion coefficient as a fixed value and realizing the multiplication circuit through shift addition, reduction of the circuit size is accomplished.

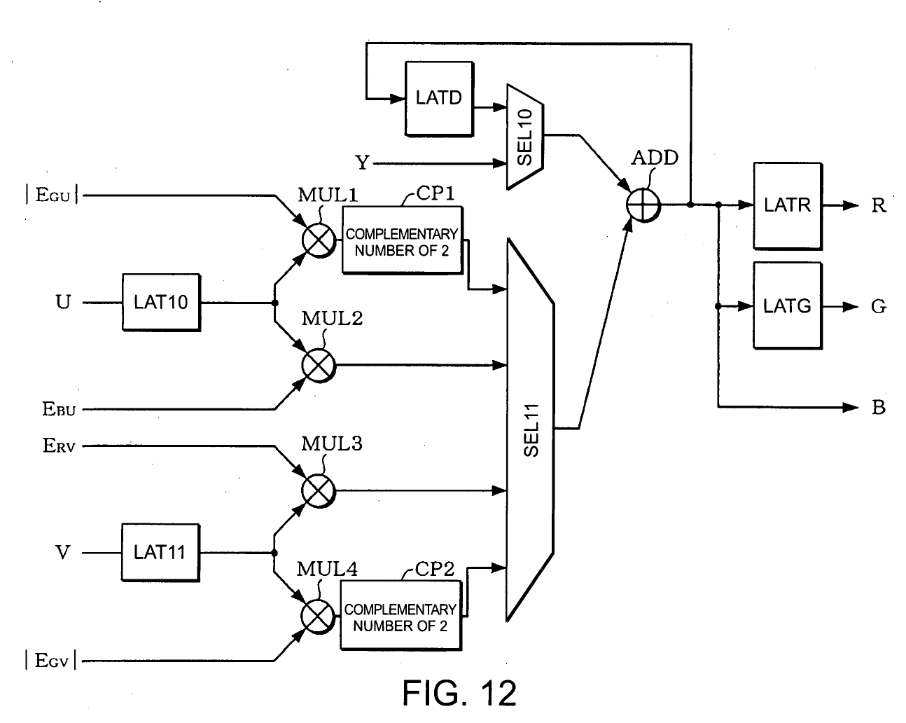

In FIG. 12, there is shown a block diagram of a hardware configuration example of the format converting circuit 260 of FIG. 6. In FIG. 12, after image data of the YUV 4:2:2 format, which is read from the video memory 210, is converted to the YUV 4:4:4 through simple interpolation as shown in FIG. 10A, it is converted to the RGB format.

In FIG. 12, there is shown a hardware configuration example when the conversion coefficients shown in FIG. 11 are E_{RY}=1.000, E_{RU}=0.000, E_{RV}=1.402, E_{GY}=1.000, E_{GU}=−0.344, E_{GV}=−0.714, E_{BY}=1.000, E_{BU}=1.772, and E_{BV}=0.000. In this case, since coefficients of the brightness component Y are all 1, the multiplication circuit can be made unnecessary. Further, since coefficients E_{RU} and E_{GV} are 0, the multiplication circuit can be made unnecessary. Still further, because coefficients E_{GU} and E_{GV} are negative values, complement circuits of 2 are provided.

A selector SEL 10 outputs selectively either the brightness component Y or a latch LATD. The LATD latches output of the adder ADD.

A selector SEL 11 selectively outputs any of E_{GU}×U, E_{BU}×U, E_{RV}×V, and E_{GV}×V. A value of E_{GU}×U may be obtained from a multiplier MULL and a complement circuit CP1 of 2. A value of E_{BU}×V may be obtained from a multiplier MUL2. A value of E_{RV}×U may be obtained from a multiplier MUL3. A value of E_{GV}×V may be obtained from a multiplier 4 and a complement circuit CP2 of 2.

The adder ADD adds each output of the Selectors SEL10 and SEL11. The output of the adder ADD is held by latches LATD, LATR, and LATG. The output of the latch LATR becomes data of an R component of image data of the RGB format. The output of the latch LATG becomes data of a G component of image data of the RGB format.

Each part of such format converting circuit 260 is controlled by a control signal from an un-illustrated format converting controller.

It is to be noted that the multipliers MUL1-MUL4 are realized by shift addition circuits.

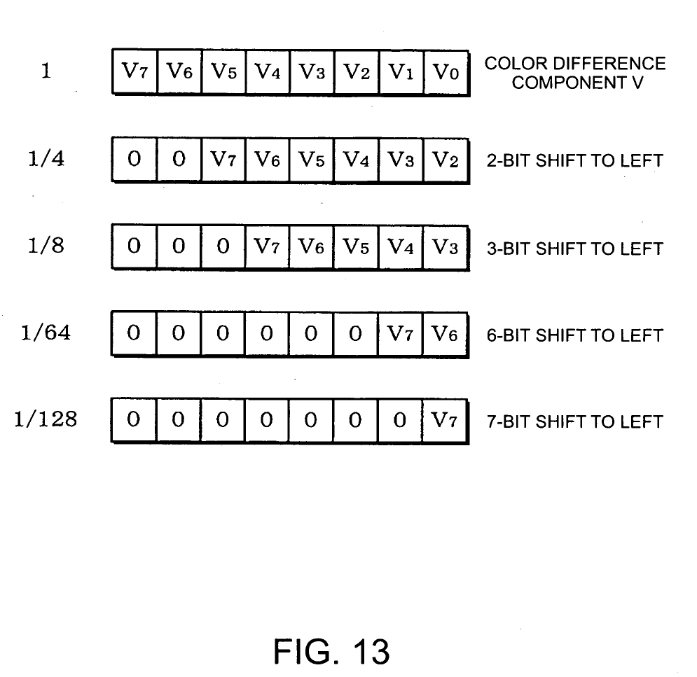

In FIG. 13, there is shown an explanatory diagram of operation of the shift addition circuits.

Here is shown an example of shift adding operation of the multiplier MUL3. As shown in FIG. 12, the multiplier MUL3 obtains a product of the color difference component V multiplied by a coefficient E_{RV} (˜1.402).

The coefficient E_{RV} value of 1.402 may be approximated as follows:
1.402=1+¼+⅛+ 1/64+ 1/128.

Here are obtained ¼ from shift operation of 2 bits to left of the color difference component V, ⅛ from shift operation of 3 bits to left of the color difference component V, 1/64 from shift operation of 6 bits to left of the color difference component V, and 1/128 from shift operation of 7 bits to left of the color difference component V.

Accordingly, assuming each bit of the color difference V of 8 bits to be V7, V6, V5 . . . V0, what is shown in FIG. 13 is obtained. As a result of this, it is possible to obtain a result of V×1.402 by adding the color difference V to the result of each shift operation of the color difference component V.

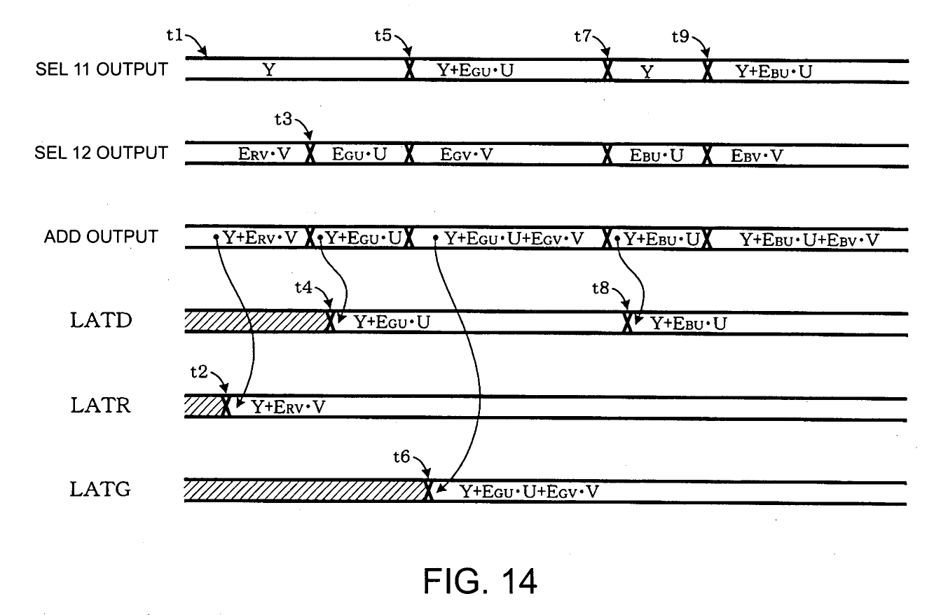

In FIG. 14, there is shown a timing diagram of an operation example of the format converting circuit 260 of FIG. 12.

At time t1, the selector SEL10 selects the brightness component Y and the selector SEL11 selects E_{RV}×V. Consequently, the adder ADD outputs Y+E_{RV}×V, and at time t2, this value is captured by the latch LATR and held as data of the R component.

Subsequently, at time t3, the selector SEL11 changes its output over to E_{GU}×U, the adder ADD outputs Y+E_{GU}×U, and at time t4, this value is captured by the latch LATD. Then at time t5, the selector SEL10 changes its output over to the latch LATD output, while the selector SEL11 changes its output over to E_{GV}×V. Consequently, the adder ADD outputs Y+E_{BU}×V, and at time t6, this value is captured by the latch LATG and held as data of the G component.

Further, at time 7, the selector SEL10 changes its output over to the brightness component Y and the selector SEL11 changes its output over to E_{GU}×U. The adder ADD outputs Y+E_{BU}×U, and at time t8, this value is captured by the latch LATD. Then at time t9, the selector SEL10 changes its output over to the latch LATD output, while the selector SEL11 changes its output over to E_{BV}×V. Consequently, the adder ADD outputs. Y+E_{BU}×U+E_{BV}×V, and this value is outputted as data of the B component.

2. 3 Image Processing Circuit

The image processing circuit 240 of FIG. 6 realizes function of the image processor 26 of FIG. 2.

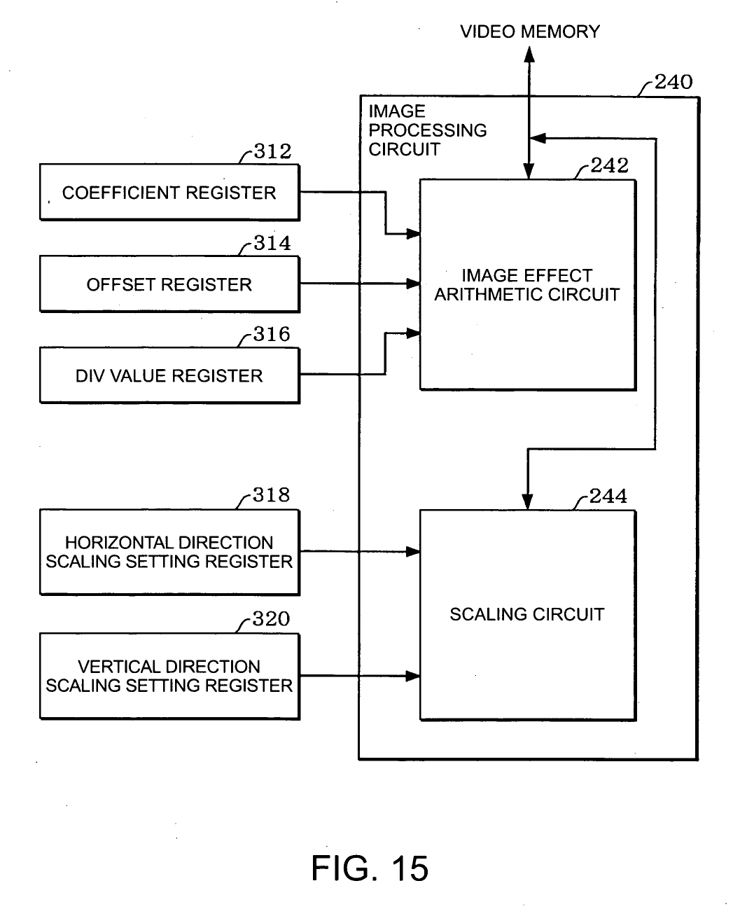

In FIG. 15, there is shown a block diagram of a configuration example of the image processing circuit 240. The image processing circuit 240 includes an image effect arithmetic circuit 242 and a scaling circuit 244. The image effect arithmetic circuit 242 performs averaging processing of a pixel with respect to image data read from the video memory 210. The scaling circuit 244 performs processing to expand or contract the image size of image data read from the video memory 210.

While it is shown in FIG. 15 that the image processing circuit 240 includes the image effect arithmetic circuit 242 and the scaling circuit 244, it may be configured such that the image processing circuit 240 includes at least one of these circuits.

The image effect arithmetic 242 performs averaging processing with respect to image data based on each set value of the coefficient register 312, the offset register 314, and the DIV value register 316. The coefficient register 312, the offset register 314, and the DIV value register 316 are included in the control register 272 of FIG. 6, the set value of each register being set by the host through the host I/F circuit 270.

The scaling circuit 244 performs processing to expand or contract image size of image data based on each set value of the horizontal direction scaling setting register 318 and the vertical direction scaling setting register 320. The horizontal direction scaling setting register 318 and the vertical direction scaling setting register 320 are included in the control register 272 of FIG. 6, the set value of each register being set by the host through the host I/F circuit 270.

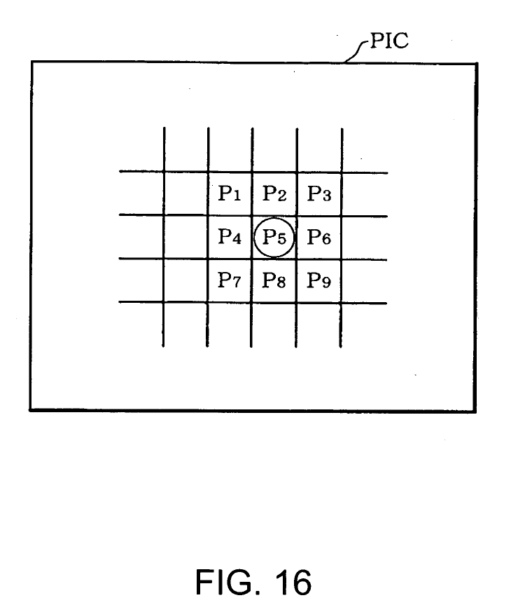

In FIG. 16, there is shown an explanatory diagram of averaging processing of image data performed by the image effect arithmetic circuit 242.

In averaging processing, a pixel value (a Y component, a U component, and a V component) of each pixel of an image PIC shown by image data is updated to a mean value together with pixel values of 8 pixels around the pixel. For example, the updated value is obtained as shown in the following equation by using each pixel value P₁-P₉ (pixel value of a pixel P₅ as P₅) of pixels P₁, P₂ . . . P₄, P₅ . . . P₉ surrounding the pixel P5 with respect to the pixel value of the pixel P₅ shown in FIG. 16, set values (k₁−k₉) of the coefficient register 312, set values (offset) of the offset register 314, and set values (DIV) of the DIV value register 316.
P₅=(offset+P₁×k₁+P₂×k₂+ . . . P₅+k₅ . . . +P₉+k₉)/DIV (1)

An update value obtained according to the above equation with respect to each of the Y component, the U component and the V component is used to update the pixel P₅. In this manner, by performing processing to each pixel of the image PIC or in terms of a specified area, it is possible to generate an effect image expressing blurring of an image.

Next, a detailed example of configuration of the scaling circuit 244 will be described. While description below is confined to the case of contracting the image size, a publicly known method for interpolating pixels may be used to realize the case of expanding the image size.

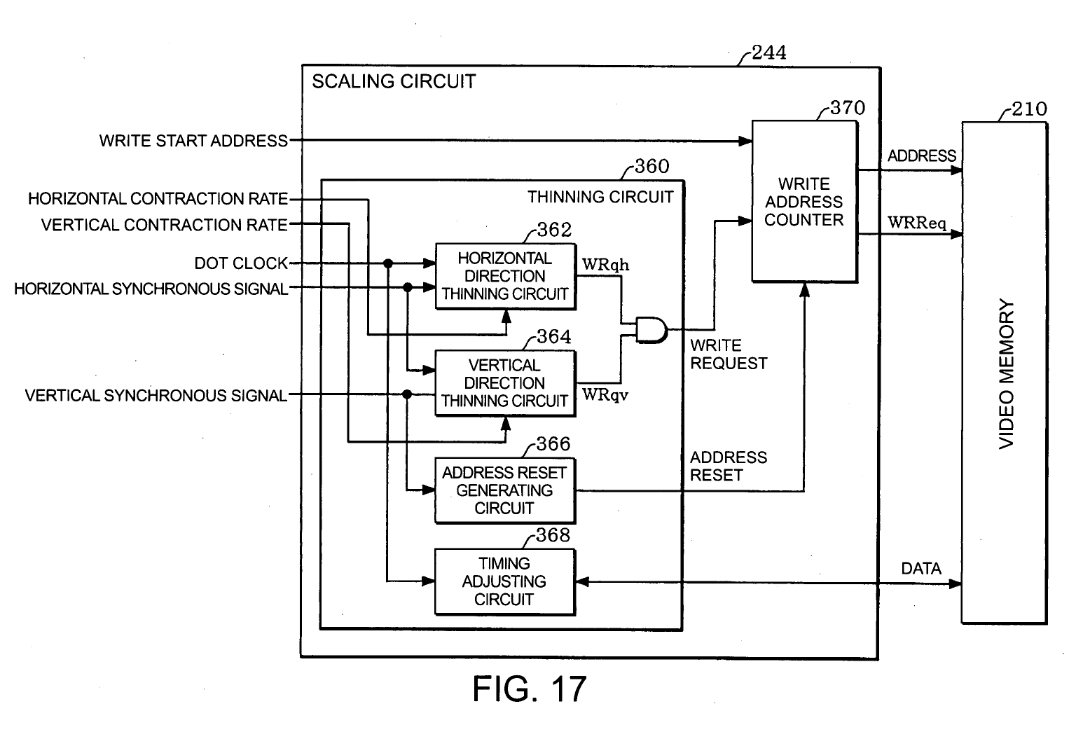

In FIG. 17, there is shown a block diagram of a configuration example of the scaling circuit 244 which performs processing to contract the image size. In FIG. 17, there is shown in outline a schematic relationship of connection between the video memory 210 and the scaling circuit 244.

In the scaling circuit 244, there are inputted the write start address, the horizontal contraction rate and the vertical contraction rate. These pieces of information are set by the host. The host sets these pieces of information in the control register 272 which includes the horizontal direction scaling setting register 318 and the vertical direction scaling setting register 330.

The write start address is a first write address for writing image data in the video memory 210. The horizontal contraction rate is a contraction rate in the horizontal direction of an image, and it is a decimal number larger than 0 and less than 1. The vertical contraction rate is a contraction rate in the vertical direction of an image, and it is a decimal number larger than 0 and less than 1.

The scaling circuit 244 includes a thinning circuit 360 and a write address counter 370. The thinning circuit 360 generates image data of an image whose size is contracted in the horizontal direction by thinning out pixels arranged in the horizontal direction according to the horizontal contraction rate. Further, the thinning circuit 360 generates image data of an image whose size is contracted in the vertical direction by thinning out pixels arranged in the vertical direction according to the vertical contraction rate. The write address counter 370 outputs a write start address by address resetting from the thinning circuit 360, and a write request from the thinning circuit 360, at a specified timing within a Level L period, adds up 1 address sequentially from the write start address from the host.

The thinning circuit 360 includes the horizontal direction thinning circuit 362, the vertical direction thinning circuit 364, an address reset generating circuit 366, and a timing adjusting circuit 368. In the thinning circuit 360, in addition to the horizontal contraction rate and the vertical contraction rate, there are inputted the dot clock, the vertical synchronous signal, the horizontal synchronous signal, and image data read from the video memory 210.

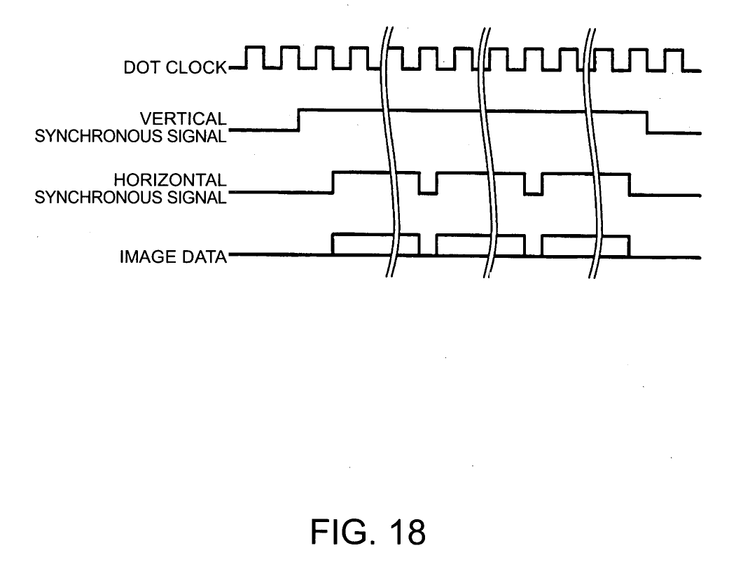

In FIG. 18, there is shown an example of a timing relationship among the dot clock, the vertical synchronous signal, the horizontal synchronous signal, and image data.

LCD control signals such as the dot clock, the vertical synchronous signal and the horizontal synchronous signal are generated by, for example, the LCD control signal generating circuit 286. The vertical synchronous signal is a signal to designate one vertical scanning period and a period of the vertical synchronous signal being on the Level L becomes one vertical scanning period. The horizontal synchronous signal is a signal to designate one horizontal scanning period and a period of the horizontal synchronous signal being on the Level H becomes one horizontal scanning period. In one horizontal scanning period, it is arranged such that image data of each pixel is sequentially inputted to the thinning circuit 360 synchronously with the dot clock.

In FIG. 17, the horizontal direction thinning circuit 362 generates a horizontal direction write request WRgh which becomes the Level H only during a period corresponding to the horizontal contraction rate within one horizontal scanning period designated by the horizontal synchronous signal. Further, the vertical direction thinning circuit 364 generates a vertical direction write request WRqv which becomes the Level H only during a period corresponding to the vertical contraction rate within one vertical scanning period designated by the vertical synchronous signal. A write request to the write address counter 370 is generated by logical product operation between the horizontal direction request WRgh and the vertical direction write request WRqv.

The address reset generating circuit 366 is constituted by a rise-up edge detection circuit. The address reset generating circuit 366 detects rise-up of the vertical synchronous signal and outputs it as an address reset.

The timing adjusting circuit 368 is constituted by data latch. The timing adjusting circuit 368 latches image data synchronously with the dot clock and outputs it as write data.

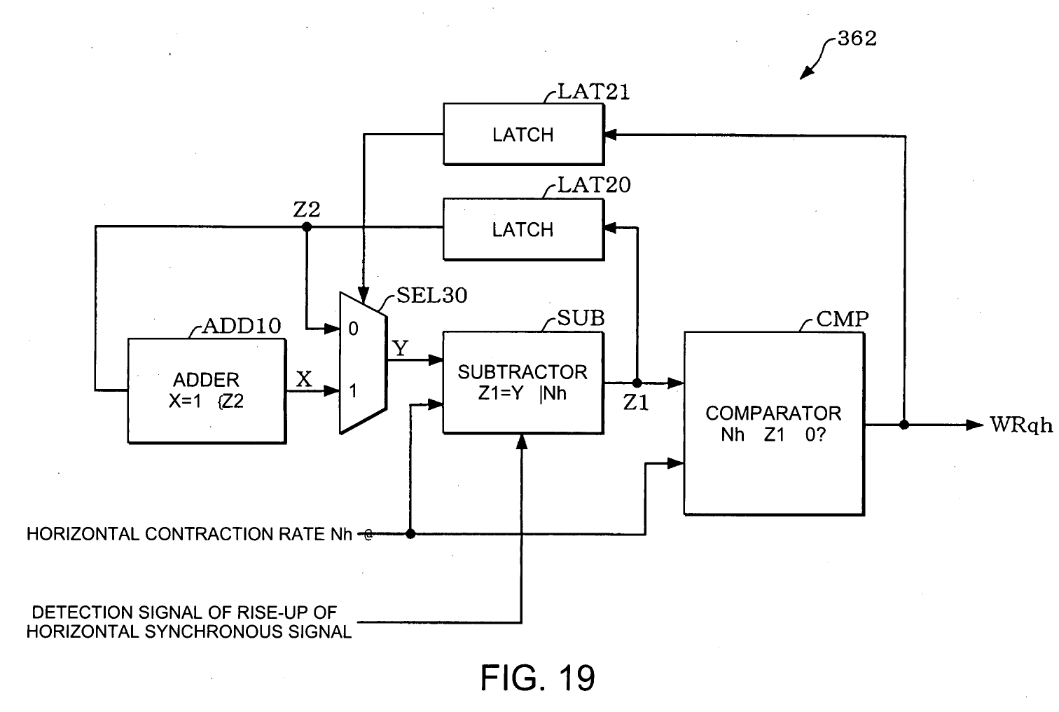

In FIG. 19, there is shown a block diagram of a configuration example of the horizontal direction thinning circuit 362.

Each part of the horizontal direction thinning circuit 362 operates synchronously with the dot clock.

A subtractor SUB outputs an output Z1 which is obtained as a decimal number by subtracting a horizontal contraction rate Nh from an input Y. The subtractor SUB initializes the output Z1 to 0 synchronously with the rise-up detection signal of the horizontal synchronous signal.

A latch LAT20 latches the output Z1 of the subtractor SUB. An output Z2 of the latch LAT20 is outputted to a selector SEL30 and an adder ADD 10.

An adder ADD10 outputs an output X obtained as a decimal number by adding 1 to the output Z2 of the latch LAT20. The output X of the adder ADD 10 is outputted to the selector SEL30.

A comparator CMP compares the output Z1 of the subtractor SUB to the horizontal contraction rate Nh. To be more specific, when the horizontal contraction rate Nh is less than the output Z1 of the subtractor SUB and the output Z1 of the subtractor SUB is more than 0, and the output Z1 of the comparator SUB is more than 0, is less than the output Z1 of the subtractor SUB, the comparator CMP has the horizontal direction write request WRgh as the level H, and in cases other than that, has the horizontal direction write request WRgh as the level L.

The output of the comparator CMP is also supplied to a latch LAT21. When an output of the latch LAT21 is 1 (level H), the selector SEL30 becomes a changeover control signal. When the output of the latch LAT21 is 1 (level H), the selector SEL30 outputs the output X of the adder ADD10, and when the output of the latch LAST21 is 0 (level L), the selector SEL30 outputs the output Z2 of the latch LAT20.

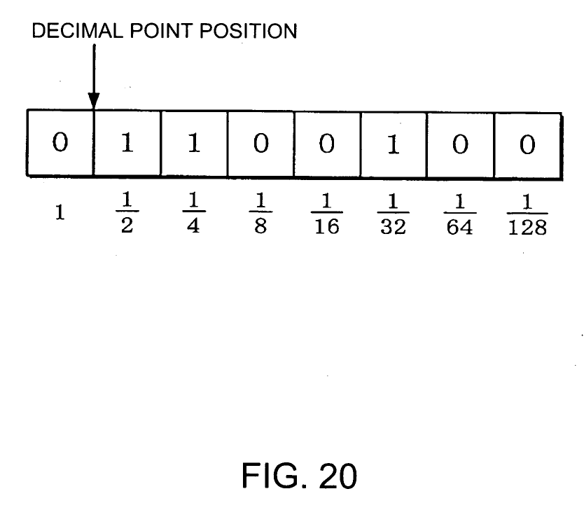

In FIG. 20, there is shown an explanatory diagram of the horizontal contraction rate Nh.

When accuracy of the horizontal direction thinning circuit 362 is set at 8 bits, the horizontal contraction rate Nh may be expressed with MSB as integer data and the remainder as data below a decimal point. For example, if the horizontal contraction rate Nh is 1, [10000000] is obtained.

In the following, with the horizontal contraction rate Nh as 0.781, an example of operation of the horizontal direction thinning circuit 362 shown in FIG. 19 will be described. When the horizontal contraction rate Nh is 0.781, approximation is obtained as 0.781=½+¼+ 1/32, whereas it may be shown as 8-bit data [01100100].

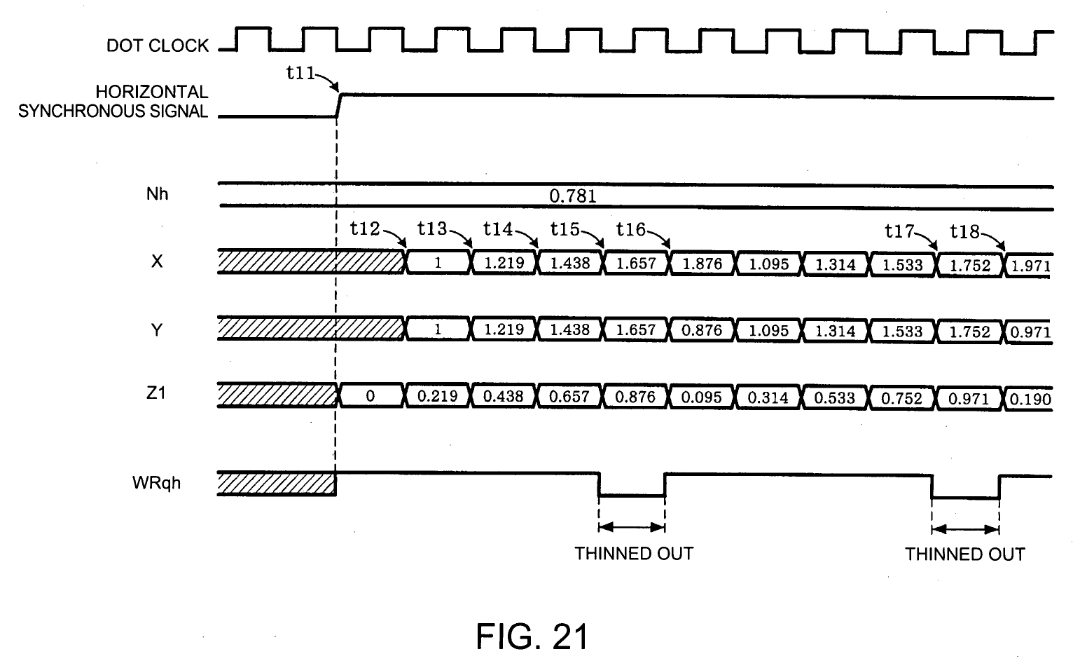

In FIG. 21, there is shown a timing diagram of an example of operation of the horizontal direction thinning circuit 362 shown in FIG. 19.

If the horizontal synchronous signal changes from the level L to the level H at time t11, the output Z1 of the subtractor SUB is initialized to 0. At this time, since the horizontal contraction rate Nh (=0.781) is larger than the output Z1 (=0) of the subtractor SUB, the output WRgh of the comparator CMP become 1 (level H).

At a trail time t12 of the next dot clock, the output of the latch LAT21 becomes 1 (level H). At this time, the latch LAT 20 captures the output Z1 of the subtractor SUB and outputs it as an output 2. The output X of the subtractor ADD10 is 1. Since the output of the latch LAT21 is 1, an output Y of the selector SEL30 becomes the output X (=1) of the adder ADD10. Consequently, the output Z1 of the subtractor SUB becomes 0.219 (=1−0.781). At this time, the horizontal contraction rate Nh (=0.781) is larger than the output Z1, hence, the output WRgh of the comparator CMP remains as 1 (level H).

Likewise, when a trailing time t13 of the next dot clock passes, the output X of the adder ADD10 becomes 1.219 and the output Z1 of the subtractor SUB becomes 0.438 (1.219-0.781). At this time, the horizontal contraction rate Nh (=0.781) is larger than the output Z1, hence, the output WRgh of the comparator CMP remains as 1 (level H).

Further, when a trailing time t14 of the next dot clock passes, the output Z1 of the subtractor SUB becomes 0.657 (1.438-0.781). At this time, the horizontal contraction rate Nh (=0.781) is larger than the output Z1, hence, the output WRgh of the comparator CMP remains as 1 (level H).

And, when a trailing time t15 of the next dot clock passes, the output Z1 of the subtractor SUB becomes 0.876 (1.657−0.781). At this time, the horizontal contraction rate Nh (=0.781) becomes less than the output Z1, hence, the output WRgh of the comparator CMP changes to 0 (level L).

And, when a trailing time t16 of the next dot clock passes, the output of the latch LAT21 becomes 0 (level L). At this time, the latch LAT20 captures the output Z1 of the subtractor SUB and outputs it as the output Z2. The output X of the adder ADD10 is 0.876. Since the output of the latch LAT21 is 0, the output Y of the selector SEL30 becomes the output Z2 (=0.876). Consequently, the output Z1 of the subtractor SUB becomes 0.095(=0.876-0.781). At this time, the horizontal contraction rate Nh (=0.781) is larger than the output Z1, hence, the output WRgh of the comparator CMP changes again to 1 (level H)

Likewise, at time t17, the output WRgh of the comparator CMP changes to 0 (level L), and at time t18, the output WRgh of the comparator CMP changes to 1 (level H).

In this manner, for a period corresponding to the horizontal contraction rate Nh (=0.781), the output WRgh of the comparator CMP can be made to be on the level H.

Up to this point, the configuration and operation of the horizontal direction thinning circuit 362 of FIG. 17 have been described. The same applied to the vertical direction thinning circuit 364 of FIG. 17. What is different is that each part of the vertical direction thinning circuit 364 operates in terms of the horizontal synchronous signal, while the subtractor is initialized by rise-up of the vertical synchronous signal, and that the vertical contraction rate Nv is inputted. Since the vertical direction thinning circuit 364 likewise can be realized, its description will be omitted.

### 3. VARIATION EXAMPLES

It is to be noted that the present invention is not limited to the configuration of the above-mentioned embodiment.

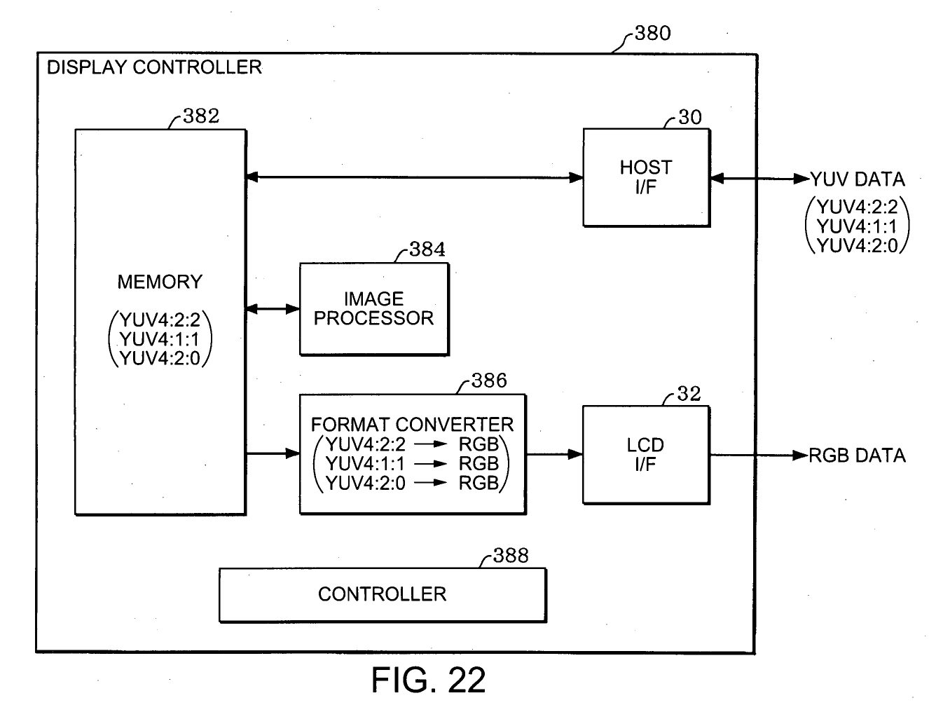

In FIG. 22, there is shown in outline a block diagram of a configuration of the display controller 20 in a variation example of the present embodiment. However, like reference numerals designate like parts of the display controller 20 shown in FIG. 2 with description omitted as necessary.

In a memory 382 which functions as the video memory of a display controller 389 in a variation example, an image of the YUV format inputted through the LCD I/F circuit 30 is inputted as is. In this case, the host supplies image data of any of the YUV 4:2:2 format, the YUV 4:1:1 format, and the YUV 4:2:0. Consequently, in the memory 382, image data is held in a condition where these formats are mixedly present.

An image processor 384 reads image data from such memory 382 and performs image processing mentioned above.

A format converter 386 converts image data of the YUV format read from the memory 382 to the RGB format. Namely, a format of the image data inputted through the host I/F circuit 30 is converted to the RGB format.

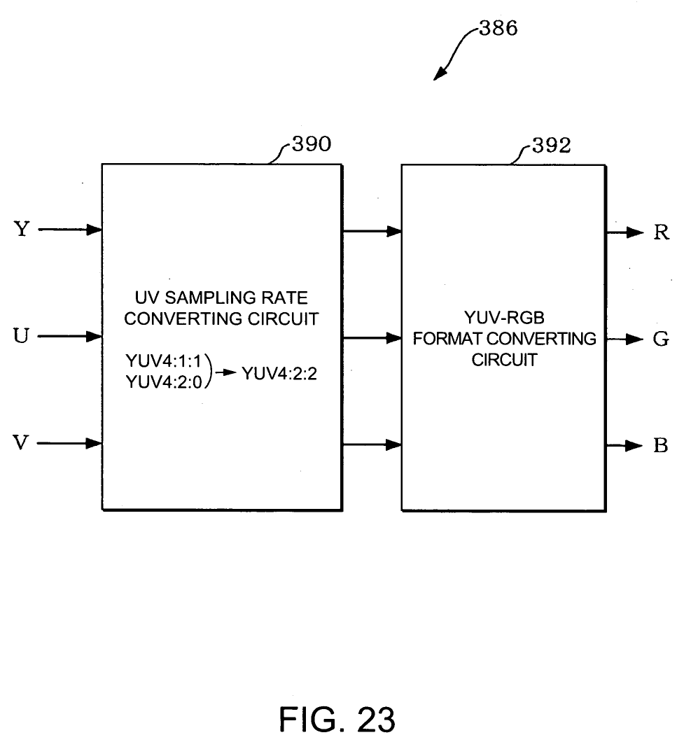

In FIG. 23, there is shown a block diagram of a configuration example of the format converter 386.

The format converter 386 includes a UV sampling rate converting circuit 390, and a YUV-RGB format converting circuit 392. The UV sampling rate converting circuit 390 converts a format of image data of the YUV 4:1:1 format or the YUV 4:2:0 format to the YUV 4:2:2 format. Such UV sampling rate converting circuit 390 may be realized by operating as shown in FIGS. 10B and C. It is to be noted that in the same way as the UV sampling rate converter 24 of the present embodiment, in a case where means of determining an input format of image data from the host is set up for image data of the YUV 4:2:2 format to be outputted as is, based on the means, without carrying out format conversion, the UV sampling rate converting circuit 390 is bypassed.

The YUV-RGB format converting circuit 392 converts image data of the YUV 4:2:2 format which has been converted by the UV sampling rate converting circuit 390 to the RGB format. Such YUV-RGB format converting circuit 392 may be realized by a configuration shown in FIG. 12.

In this manner, when inputted image data is of the YUV 4:2:2 format, the format converter 386 makes a conversion to the RGB format. Further, when inputted image data is of the YUV 4:1:1 format, the format converter 386 makes a conversion to the RGB format. Still further, when inputted image data is of the YUV 4:2:0 format, the format converter 386 makes a conversion to the RGB format. And image data of the RGB format which has been converted by the format converter 386 is supplied to the display driver through the LCD I/F circuit 32.

In the present example of variation, a controller 388 takes charge of controlling each part of a display controller 380.

In this manner, in the present example of variation, although it is necessary for all the YUV formats of image data inputted into the format converter 386 to be able to be converted to the RGB format, there is obtained an effect of reducing capacity of the memory 382.

4. Electronic Equipment

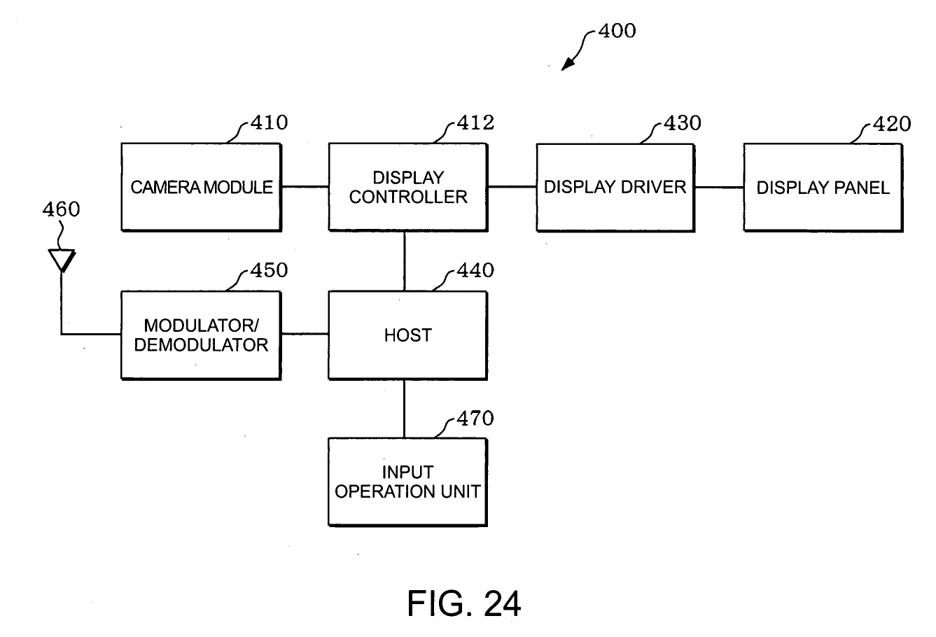

In FIG. 24, there is shown a block diagram of a configuration example of electronic equipment to which a display controller is applied in the present embodiment or its example of variation. Here is shown a block diagram of a configuration example of a mobile phone as electronic equipment.

A mobile phone 400 includes a camera module 410. The camera module 410 includes a CCD camera, supplying data of images picked up by the CCD camera and supplying it in the YUV format to a display controller 412. As the display controller 412, the display controller 20, 200 in the present embodiment or the display controller 380 in the present example of variation may be employed.

The mobile phone 400 includes a display panel 420. As the display panel 420, a liquid crystal display panel may be used. In this case, the display panel 420 is driven by a display driver 430. The display panel 420 includes a plurality of scanning lines, a plurality of data lines, and a plurality of pixels. The display driver 430 has a function of a scanning driver which selects one of a plurality of scanning lines or scanning lines in units of a plurality of lines, while, at the same time, having a function of a data driver supplying a voltage corresponding to image data to a plurality of data lines.

The display controller 412 is connected to the display driver 430, supplying image data of the RGB format with respect to the display driver 430.

A host 440 is connected to the display controller 412. The host 440 controls the display controller 412. Further, the host 440, after demodulating image data received through an antenna 460 at a modulator/demodulator 450, can supply it to the display controller 412. The display controller 412, based on this image data, causes the display panel 420 to display it through the display driver 430.

The host 440, after modulating image data generated by the camera module 410 at the modulator/demodulator 450, can instruct its transmission to other communications devices through the antenna 460.

The host 440, based on operating information from an operating input unit 470, performs processing to send or receive image data, image pickup of the camera module 410, and display processing of the display panel.

It is to be noted that in FIG. 24, as the display panel 420, a liquid crystal display panel was cited for explanation, but it is not limited to this apparatus. The display panel 420 may be equipment of electro-luminescence and a plasma display device, and it is applicable to the display controller supply image data to the display driver driving these devices.

It is to be understood that the present invention is not limited to the embodiments described above, and that various changes and modifications may be made within the spirit of the present invention.

Further, with regards to that part of the present invention pertaining to dependent claims, it is possible to form a constitution of the invention omitting part of the constituent features of dependent claims. Further, features of the invention pertaining to one dependent claim of the present invention may be made to be dependent upon other dependent claims.

1. A display controller for supplying image data to a display driver driving a display panel, comprising:
a UV sampling rate converter converting an image data format of a first YUV format from a host to a second YUV format by changing sampling rates of a U component and a V component of the image data;
a memory in which image data of the second YUV format converted by the UV sampling rate converter is stored;
an image processor which subjects image data of the second YUV format read from the memory to specified image processing and writes the image data after image processing as is in the second YUV format in the memory; and
a format converter converting image data of the second YUV format read from the memory to an RGB format, wherein image data converted by the format converter to the RGB format is supplied to the display driver.

2. The display controller according to claim 1, wherein the UV sampling rate converter converts image data of the second YUV format read from the memory to the first YUV format by changing the sampling rates of the U component and the V component of the image data, and image data of the first YUV format converted by the UV sampling rate converter is supplied to the host.

3. The display controller according to claim 1, wherein the first YUV format is a YUV 4:1:1 format or a YUV 4:2:0 format, and the second YUV format is a YUV 4:2:2 format.

4. The display controller according to claim 1, further comprising:
an input format setting register for setting an input format of image data from the host, wherein the first YUV format is the YUV 4:1:1 format, the YUV 4:2:0 format, or the YUV 4:2:2 format, the second YUV format being the YUV 4:2:2 format, and when it is determined that image data from the host is the YUV 4:2:2 format based on a set value of the input format setting register, the UV sampling rate converter supplies the image data from the host as it is to the memory.

5. The display controller for supplying image data to the display driver driving the display panel, comprising:
a host interface for inputting image data of the first YUV format from the host;
a memory in which image data of the first YUV format inputted through the host interface is stored;
an image processor which subjects image read from the memory to specified image processing and writing image data without changing the format of the image data after image processing in the memory; and
a format converter converting image data of the first YUV format read from the memory to the RGB format, wherein image data converted by the format converter to the RGB format is supplied to the display driver.

6. The display controller according to claim 5, wherein the format converter, after converting the image data format of the first YUV format read from the memory to the second YUV format by changing sampling rates of the U component and the V component of the image data, converts the image data to the RGB format.

7. The display controller according to claim 1, further comprising:
a display driver interface for supplying image data of the RGB format converted by the format converter.

8. The display controller according to claim 1, wherein the image processor includes at least one of a scaling circuit performing processing to enlarge or reduce an image size of the image data read from the memory and an image effect arithmetic circuit performing specified effect processing with respect to the image data read from the memory.

9. Electronic equipment comprising a display panel, a display controller according to claim 1; and
a display driver driving the display panel based on image data supplied by the display controller.

10. Electronic equipment according to claim 9, further comprising a host performing input and output of image data between itself and the display controller.

11. An image data supplying method for supplying image data to a display driver driving a display panel, converting a format of image data of a first YUV format from a host to a second YUV format by changing sampling rates of a U component and a V component of the image data;
storing image data of the second YUV format in a memory;
converting a format of image data read from the memory to an RGB format and sending output thereof to the display driver; and
the image data stored in the memory being applied with specified image processing after being once read from the memory and being written in the memory again after image processing.

12. The image data supplying method for supplying image data to a display driver driving a display panel, storing the format of image data of the first YUV format from the host without making a change thereof;
converting a format of image data read from the memory to the RGB format and outputting it to the display driver; and
the image data stored in the memory being applied with specified image processing after being once read from the memory and being written in the memory again after image processing.
